(19) United States
(12) Patent Application Publication
(10) Pub. No.: US 2026/0109088 A1
(43) Pub. Date: Apr. 23, 2026

(54) COMPRESSION RESIN SEALING MOLDING DEVICE

(71) Applicant: Murata Manufacturing Co., Ltd., Nagaokakyo-shi (JP)

(72) Inventors: Koichi KANRYO, Nagaokakyo-shi, Kyoto (JP); Katsuki NAKANISHI, Nagaokakyo-shi, Kyoto (JP)

(73) Assignee: Murata Manufacturing Co., Ltd., Nagaokakyo-shi (JP)

(21) Appl. No.: 19/424,349

(22) Filed: Dec. 18, 2025

Related U.S. Application Data
(63) Continuation of application No. PCT/JP2024/011573, filed on Mar. 25, 2024.

(30) Foreign Application Priority Data
Jul. 24, 2023 (JP) 2023-120124

(51) Int. Cl. B29C 43/18; B29L 31/34; H10W 74/01

(52) U.S. Cl. CPC B29C 43/18; H10W 74/016; B29C 2043/181; B29L 2031/3406

(57) ABSTRACT

A compression resin sealing molding device for molding a sealing resin layer on a substrate having a first surface and a second surface opposite to each other. The device includes a lower mold facing the first surface and an upper mold that abuts the second surface. The lower mold includes an outer frame and an inner frame, at least part of the inner frame being vertically displaceable with respect to the outer frame. The outer frame is configured to abut the upper mold outside the substrate to determine a fixed distance between the lower mold and the upper mold. The inner frame has two states: a first state in which a resin is confined in an inner region of the inner frame and a second state achieved when the outer frame abuts the upper mold and excess resin is leaked outside of the inner frame into an overflow region.

### CROSS-REFERENCE TO RELATED APPLICATIONS

This application is a continuation of International Application No. PCT/JP2024/011573, filed on Mar. 25, 2024, which claims priority to Japanese Patent Application No. 2023-120124, filed on Jul. 24, 2023. The entire disclosures of the prior applications are hereby incorporated by reference in their entirety.

### TECHNICAL FIELD

The present disclosure relates to a compression resin sealing molding device.

### BACKGROUND ART

Japanese Patent Laying-Open No. 2015-162553 (PTL 1) describes a resin molding device of a semiconductor device. The resin molding device includes a clamp plate connected to a lower mold by a spring. The clamp plate is arranged so as to surround the outer circumference of a cavity and includes an annular protruding portion. The annular protruding portion comes into contact with a back surface of a semiconductor wafer at the time of clamping to clamp the semiconductor wafer.

PTL 1 further describes a configuration in which a stopper is provided. It is described that, in this case, the clamp plate is stopped by the stopper, and thus, the wafer is not pressed beyond a set value. It is described that, accordingly, the wafer can be prevented from incurring damage through excessive clamping.

### CITATION LIST

### Patent Literature

PTL 1: Japanese Patent Laying-Open No. 2015-162553

### SUMMARY

### Technical Problems

In PTL 1, the load that the clamp plate applies to the semiconductor device can be controlled by using the stopper but the thickness of the semiconductor device cannot be controlled. The thickness of the resin formed in the semiconductor device is controlled according to the amount of the resin to be supplied.

However, the thickness of the substrate used in the semiconductor device may vary. If the variation in the thickness of the substrate is large even when the amount of the resin to be supplied is properly controlled, the thickness of a product as a whole (hereinafter referred to as the “product thickness”) in which the substrate and the resin layer are combined does not necessarily have a desired value.

Thus, the present disclosure is directed to providing a compression resin sealing molding device capable of controlling the product thickness easily and accurately.

### Solutions to Problems

To achieve the above-described object, a compression resin sealing molding device based on the present disclosure is a compression resin sealing molding device for molding a sealing resin layer so as to cover at least part of a first surface of a substrate while sealing a component arranged on the first surface of the substrate, the substrate including the first surface and a second surface opposite to each other, the compression resin sealing molding device including a lower mold facing the first surface, and an upper mold that abuts on the second surface. In the compression resin sealing molding device, the lower mold includes an outer frame and an inner frame, at least part of the inner frame being relatively displaceable in an up-and-down direction with respect to the outer frame, the outer frame is abuttable on the upper mold outside the substrate, the inner frame is capable of taking a first state in which a resin material being a material of the sealing resin layer is confined in an inner region of the inner frame and pressurized, and a second state in which part of the resin material is held in the inner region of the inner frame while another part of the resin material is leaked outside of the inner frame. A distance between a portion of the lower mold other than the outer frame and the upper mold at a time when the lower mold and the upper mold are closest to each other is determined by the outer frame abutting on the upper mold.

### Advantageous Effects

According to the present disclosure, the product thickness can be controlled easily and accurately by causing the distance between the lower mold and the upper mold to be a desired distance using the outer frame while part of the resin material is leaked outside of the inner frame.

### BRIEF DESCRIPTION OF DRAWINGS

FIG. 1 is a cross-sectional view of a state in which a substrate and a powder resin material are placed in a compression resin sealing molding device according to a first embodiment based.

FIG. 2 is a plan view in a state where only an outer frame and an inner frame are taken out from the compression resin sealing molding device according to the first embodiment.

FIG. 3 is a cross-sectional view of a state in which a lower mold is relatively close to an upper mold in the compression resin sealing molding device according to the first embodiment.

FIG. 4 is a cross-sectional view of a state in which the inner frame is lowered in the compression resin sealing molding device according to the first embodiment.

FIG. 5 is a plan view of a molded object obtained in the compression resin sealing molding device according to the first embodiment.

FIG. 6 is a cross-sectional view of the molded object obtained in the compression resin sealing molding device according to the first embodiment.

FIG. 7 is an explanatory view on how an unnecessary portion of the molded object obtained in the compression resin sealing molding device according to the first embodiment \ is removed.

FIG. 8 is an explanatory view on how an operation is started from a state in which the substrate is held toward the upper mold in the compression resin sealing molding device according to the first embodiment.

FIG. 9 is a plan view in a state where only an outer frame and an inner frame are taken out from a compression resin sealing molding device according to a second embodiment invention.

FIG. 10 is a cross-sectional view of a state in which a substrate and a powder resin material are placed in the compression resin sealing molding device according to the second embodiment.

FIG. 11 is a cross-sectional view of a state in which a lower mold is relatively close to an upper mold in the compression resin sealing molding device according to the second embodiment.

FIG. 12 is an explanatory view on that a passage for an air vent is provided in the inner frame of the compression resin sealing molding device according to the second embodiment.

FIG. 13 is a cross-sectional view of a state in which an inner frame second portion is lowered in the compression resin sealing molding device according to the second embodiment.

FIG. 14 is an explanatory view on how the inner frame appears in the state illustrated in FIG. 13.

FIG. 15 is a plan view of a molded object obtained in the compression resin sealing molding device according to the second embodiment.

FIG. 16 is an explanatory view about placing an object after the molding operation on a rack.

FIG. 17 is a cross-sectional view of a state in which a substrate and a powder resin material are placed in a compression resin sealing molding device according to a third embodiment.

FIG. 18 is a cross-sectional view of a state in which a lower mold is relatively close to an upper mold in the compression resin sealing molding device according to the third embodiment.

FIG. 19 is a cross-sectional view of a state in which an inner frame is lowered in the compression resin sealing molding device according to the third embodiment.

FIG. 20 is a plan view of a molded object obtained in the compression resin sealing molding device according to the third embodiment based on the present invention.

FIG. 21 is a cross-sectional view of the molded object obtained in the compression resin sealing molding device according to the third embodiment.

FIG. 22 is an explanatory view on how a portion protruding from the molded object obtained in the compression resin sealing molding device according to the third embodiment is cut off.

FIG. 23 is an explanatory view on how individual modules are cut out from the molded object obtained in the compression resin sealing molding device according to the third embodiment.

FIG. 24 is an explanatory view on how an operation is started from a state in which the substrate is held toward the upper mold in the compression resin sealing molding device according to the third embodiment.

FIG. 25 is a cross-sectional view of a state in which a substrate and a powder resin material are placed in a compression resin sealing molding device according to a fourth embodiment.

FIG. 26 is a cross-sectional view of a state in which a lower mold is relatively close to an upper mold in the compression resin sealing molding device according to the fourth embodiment.

FIG. 27 is a cross-sectional view of a state in which an inner frame is lowered in the compression resin sealing molding device according to the fourth embodiment.

FIG. 28 is a plan view of a molded object obtained in the compression resin sealing molding device according to the fourth embodiment.

FIG. 29 is a cross-sectional view of a state in which a substrate and a powder resin material are placed in a compression resin sealing molding device according to a fifth embodiment.

FIG. 30 is a cross-sectional view of a state in which a lower mold is relatively close to an upper mold in the compression resin sealing molding device according to the fifth embodiment.

FIG. 31 is a cross-sectional view of a state in which an inner frame second portion is lowered in the compression resin sealing molding device according to the fifth embodiment.

FIG. 32 is a cross-sectional view of the molded object obtained in the compression resin sealing molding device according to the fifth embodiment.

FIG. 33 is a cross-sectional view of a state in which a substrate and a powder resin material are placed in a compression resin sealing molding device according to a sixth embodiment.

FIG. 34 is a cross-sectional view of a state in which a lower mold is relatively close to an upper mold in the compression resin sealing molding device according to the sixth embodiment based on the present invention.

FIG. 35 is a cross-sectional view of a state in which an inner frame second portion is lowered in the compression resin sealing molding device according to the sixth embodiment.

### DESCRIPTION OF EMBODIMENTS

The dimensional ratios shown in the drawings do not necessarily faithfully represent those in practice but may be indicated through exaggeration for convenience of explanation. When a concept of the upper or lower side is mentioned in the following description, it does not necessarily mean the absolute upper or lower side but may mean the relative upper or lower side in the orientation illustrated.

### First Embodiment

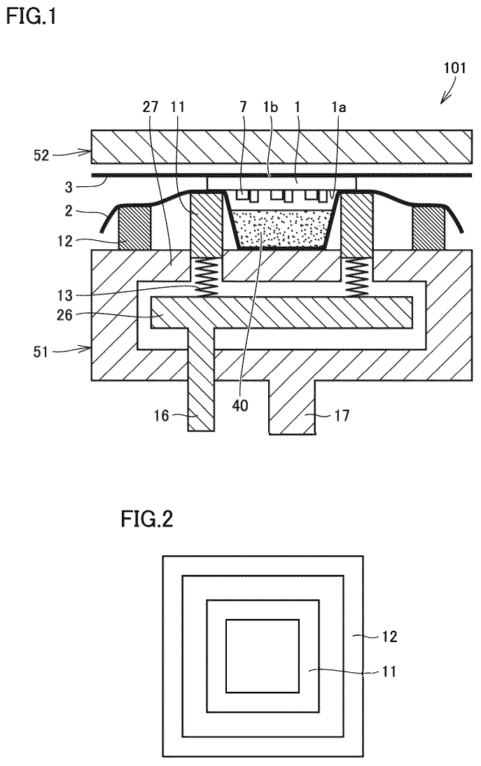

A compression resin sealing molding device according to a first embodiment based on the present disclosure is described with reference to FIGS. 1 to 7.

Hereinafter, when that an A member and a B member abut on each other is mentioned, it includes not only a case in which the A member and the B member directly abut on each other without anything interposed therebetween but also includes a case in which the A member and the B member abut on each other with a thin sheet interposed therebetween. That is, even in the state where a thin sheet is interposed between the A member and the B member, the A member and the B member may be expressed as being abutting on each other. The number of the thin sheets interposed is not limited to one but may be two or more.

FIG. 1 shows a cross-sectional view of compression resin sealing molding device 101 according to the present embodiment. A substrate 1, a component 7, release sheets 2 and 3, and a powder resin material 40 are not part of compression resin sealing molding device 101 but are also illustrated in the cross-sectional view of compression resin sealing molding device 101 for convenience of explanation. The same applies to the following drawings.

Compression resin sealing molding device 101 according to the present embodiment is a compression resin sealing molding device for molding a sealing resin layer so as to cover at least part of a first surface 1a of substrate 1 while sealing component 7 arranged on first surface 1a of substrate 1 including first surface 1a and a second surface 1b opposite to each other. This compression resin sealing molding device 101 includes a lower mold 51 facing first surface 1a and an upper mold 52 that abuts on second surface 1b. Lower mold 51 is relatively movable with respect to upper mold 52. Lower mold 51 includes an outer frame 12 and an inner frame 11, at least part of which is relatively displaceable in an up-and-down direction with respect to outer frame 12, i.e., vertically displaceable. That is, the entire inner frame 11 may be configured to be relatively displaceable in the up-and-down direction with respect to outer frame 12, or part of inner frame 11 may be configured to be relatively displaceable in the up-and-down direction with respect to outer frame 12.

To present the positional relation between outer frame 12 and inner frame 11, FIG. 2 shows a plan view in a state where only outer frame 12 and inner frame 11 are taken out. Outer frame 12 and inner frame 11 each have an annular shape. Outer frame 12 is arranged so as to surround inner frame 11. Here, an example in which outer frame 12 has a continuous annular shape along the entire circumference is presented, but outer frame 12 is not limited to such a complete annular shape. For example, outer frame 12 may be divided into a plurality of sections and intermittently arranged in an annular shape. Alternatively, outer frame 12 may be arranged so that a plurality of blocks are interspersed.

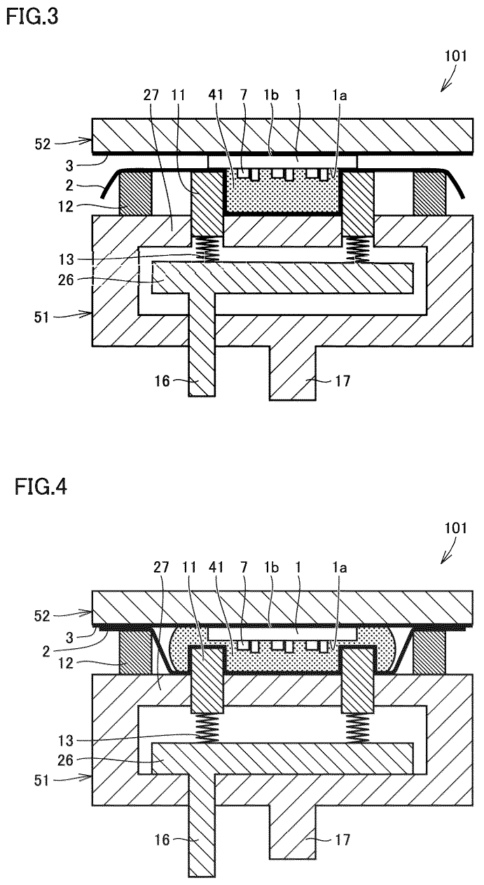

Outer frame 12 is abuttable on upper mold 52 outside substrate 1. Inner frame 11 can take a first state in which a resin material being a material of the sealing resin layer is confined in an inner region of inner frame 11, i.e., the volume defined by the inner frame's upper surface, its inner wall, and the substrate's first surface, and pressurized, and a second state in which part of the resin material is held in the inner region of inner frame 11 while another part of the resin material is leaked outside of inner frame 11. The “resin material” mentioned herein is powder resin material 40 in FIG. 1. The resin material is melted later to turn a resin material 41 as in FIGS. 3 and 4.

FIG. 1 shows a state in which powder resin material 40 is placed in compression resin sealing molding device 101. Release sheet 2 is placed over lower mold 51, and powder resin material 40 is arranged in a central cavity. Substrate 1 is placed over release sheet 2. Substrate 1 is placed in an orientation in which first surface 1a faces downward. Component 7 is mounted on first surface 1a of substrate 1.

Substrate 1 may undergo a process, such as Ar plasma cleaning, plasma cleaning using O₂ radicals, or light cleaning using UV light or the like, before being placed in this position. By performing these processes on substrate 1, cleaning, surface modification, and the like are achieved. These processes are performed on substrate 1 on which a component is mounted. These processes for cleaning and surface modification may be performed by any method as long as it is a method for increasing adhesion between the sealing resin and the substrate and adhesion between the sealing resin and the component. For example, in the case of the plasma cleaning, it may be either of a DP mode and an RIE mode. The gas used in the process may be any of Ar, N₂, O₂, CF₄, and the like or may be a mixture of two or more of these gases. When the light cleaning is adopted, the light source used may be any type of light source from among a low-pressure mercury lamp, an excimer lamp, and the like.

The outer edge of substrate 1 is placed over inner frame 11 with release sheet 2 interposed therebetween. However, substrate 1 does not completely cover an upper surface of inner frame 11 but covers part of the upper surface of inner frame 11. Release sheet 3 is placed on substrate 1.

Lower mold 51 includes a member 26, a member 27, an inner frame drive shaft 16, and a base drive shaft 17. Outer frame 12 is supported by member 27. Inner frame 11 is supported by member 26 with a spring 13 interposed therebetween. Inner frame drive shaft 16 extends from member 26. Base drive shaft 17 extends from member 27. Member 26 is relatively movable in the up-and-down direction with respect to member 27. The position of inner frame 11 in the up-and-down direction can be determined by moving inner frame drive shaft 16 upward and downward. The position of outer frame 12 in the up-and-down direction can be determined by moving base drive shaft 17 upward and downward.

FIG. 3 shows a state in which lower mold 51 is brought relatively closer to upper mold 52 from the state illustrated in FIG. 1. In this state, substrate 1 sandwiched between release sheets 2 and 3 is sandwiched and fixed between inner frame 11 of lower mold 51 and upper mold 52. The resin material is melted in the cavity and turns resin material 41. Resin material 41 is confined inside inner frame 11. Resin material 41 covers part of first surface 1a of substrate 1. The state illustrated in FIG. 3 is a first state. In this first state, pressure at a given value can be applied to resin material 41. Thus, a gap between component 7 and substrate 1 (which is hereinafter referred to as the “space under the components”) can also be sufficiently filled with resin material 41. In addition, by applying sufficient pressure to the entire resin material 41, it is enabled to prevent generation of a void. In the first state, the pressure may be applied to resin material 41 without leaking any resin material 41 at all, or air or resin material 41 may be leaked to the extent that allows desired internal pressure to be secured.

In the first state illustrated in FIG. 3, as compared with the state illustrated in FIG. 1, inner frame 11 is lowered so as to sink with respect to member 27 through elastic deformation of spring 13. At this time, the capacity that allows resin material 41 to be housed inside inner frame 11 is decreased by inner frame 11 being lowered, and resin material 41 is pressurized accordingly. In other words, inner frame 11 is supported with spring 13 as an elastic body interposed in between, and in the first state, resin material 41 confined in the inner region of inner frame 11 is pressurized through the elastic deformation of the elastic body on inner frame 11. In the example presented here, spring 13 is placed under inner frame 11 so as to lower inner frame 11. However, under inner frame 11, an elastic body other than spring 13 may be placed, or an air cylinder or the like may be placed.

That is, any structure may be adopted as long as in the structure, resin material 41 is pressed by member 27 and pressurized by inner frame 11 being relatively lowered with respect to member 27 after lower mold 51 moves relatively close to upper mold 52 and inner frame 11 comes into contact with upper mold 52.

FIG. 4 shows a state in which lower mold 51 is brought relatively still closer to upper mold 52 and inner frame 11 is lowered further from the state illustrated in FIG. 3. The movement of lowering inner frame 11 can be achieved by, for example, lowering inner frame drive shaft 16. The movement of lowering inner frame 11 may be achieved not only by lowering inner frame drive shaft 16, but also achieved by, for example, placing an air cylinder or the like on the lower side of inner frame 11 and using the working of the air cylinder.

The structure of the portions related to inner frame 11 is not limited to the above-described example. For the structure of the portions related to inner frame 11, any mechanism and method may be adopted as long as, when lower mold 51 moves relatively closer to upper mold 52, from the state illustrated in FIG. 1, inner frame 11 can reach the state in FIG. 3 by following and becoming lowered and inner frame 11 can reach the state in FIG. 4 by relatively becoming lowered further with respect to member 27.

In FIG. 4, a gap is formed between a lower surface of substrate 1 and the upper surface of inner frame 11, and resin material 41 leaks to the outside accordingly. However, resin material 41 that has leaked outside of inner frame 11 in this manner remains in a region inside outer frame 12. The state illustrated in FIG. 4 is a second state. The space defined between the innermost wall of the outer frame 12 and the outermost wall of the inner frame 11 defines an overflow region, which is a containment zone for the displaced resin. When the device 101 is in the second state, where the inner frame 11 is lowered, a portion of the liquid resin material 41 flows into this overflow region, preventing unwanted spillage outside the lower mold 51 while ensuring the final package thickness is determined solely by the outer frame's abutment with the upper mold 52.

The distance between a portion of lower mold 51 other than outer frame 12 and upper mold 52 at the time when lower mold 51 and upper mold 52 are closest to each other is determined by outer frame 12 abutting on upper mold 52. That is, in the state in FIG. 4, outer frame 12 acts as a stopper so as to establish a fixed minimum gap, which defines the predetermined final product thickness between the portion of lower mold 51 other than outer frame 12 and upper mold 52 to be a desired distance. The distance between an upper surface of member 27 of lower mold 51 and a lower surface of upper mold 52 is accurately determined by the height of outer frame 12.

Although outer frame 12 is exemplified as a frame-shaped member here, it is not necessarily limited to the frame shape but may be a plurality of divided and arranged blocks. The portion corresponding to outer frame 12 may have any structure as long as in the structure, it functions as a stopper for causing the distance between the portion of lower mold 51 other than outer frame 12 and upper mold 52 to be a desired distance.

When clamping can be performed between lower mold 51 and upper mold 52, that is, when lower mold 51 is further pressed upward from the state in FIG. 3, inner frame 11 slightly sinks through the elastic deformation of spring 13. Since inner frame 11 is urged upward by the force of spring 13, resin material 41 does not leak immediately even when inner frame 11 is displaced downward. However, in the state in FIG. 4 reached thereafter, resin material 41 is intentionally leaked by lowering inner frame drive shaft 16. At this time, the amount of the downward displacement of inner frame 11 is sufficiently large and resin material 41 can leak through a gap.

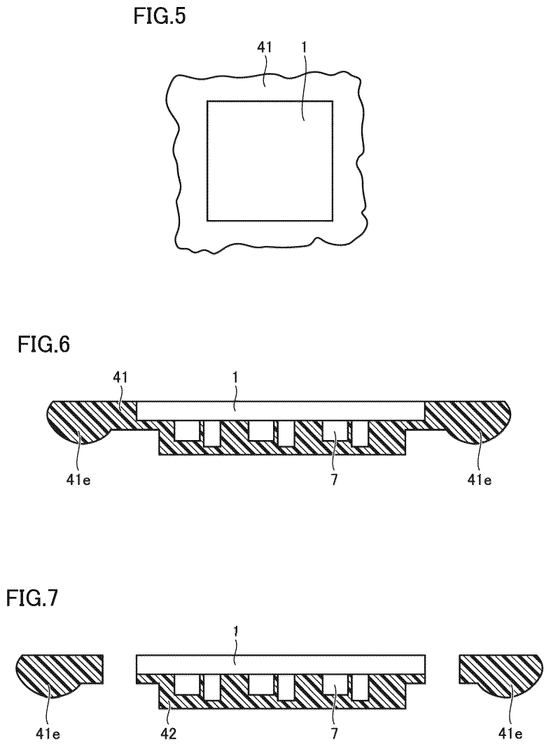

Since resin material 41 is hardened in the state where part of resin material 41 is leaked outside of inner frame 11, the molded object obtained appears as in FIG. 5 when shown in a plan view. An upper surface of substrate 1 is exposed, and the leaked resin material 41 is hardened and adheres to the outer periphery thereof in an indefinite shape. FIG. 6 shows a cross-sectional view of this state. A protruding portion 41e of resin material 41 is contiguous to both ends. As illustrated in FIG. 7, portion 41e is cut off. Portion 41e may be removed by being cracked. A sealing resin layer 42 is formed so as to seal component 7. Furthermore, when this state corresponds to an aggregate of a plurality of products, cutting separation is performed according to the size of each individual product.

As illustrated in FIG. 4, resin material 41 may be hardened in the state where inner frame 11 is lowered, but inner frame 11 may be raised before resin material 41 is hardened and then resin material 41 may be hardened. By hardening resin material 41 after raising inner frame 11, resin material 41 in the region overlapping the upper surface of inner frame 11 is made still thinner than that illustrated in FIG. 6, and accordingly, the operation of dividing and removing protruding portion 41e is facilitated.

In the present embodiment, the thickness of the product including substrate 1 and sealing resin layer 42 is controlled easily and accurately by using the outer frame 12 to set a maximum compression distance between the lower mold 51 and the upper mold 52, which defines the final product thickness, while the inner frame 11 displaces excess resin material 41 to the outside. Even if there is a variation in the thickness of substrate 1 or there is a portion where no component is mounted in the product, such a variation or portion can be dealt with since the amount of resin material 41 to be leaked can be changed by itself, and as a result, the product thickness of a desired value can be obtained with high accuracy. As described above, according to the present embodiment, it is possible to attain the compression resin sealing molding device capable of easily controlling the thickness of the resin formed in the target product.

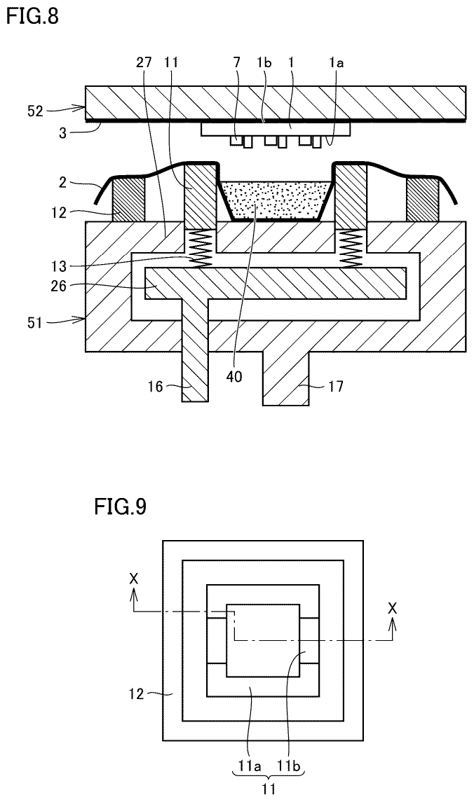

In the present embodiment, the operation is started from the state in which substrate 1 is placed over lower mold 51 but the operation may be started from the state in which substrate 1 is held toward upper mold 52 as illustrated in FIG. 8. In FIG. 8, release sheet 3 is held on the lower surface of upper mold 52 and substrate 1 is held on a lower surface of release sheet 3. To hold release sheet 3 on the lower surface of upper mold 52, an upper surface of release sheet 3 may be given adhesiveness and release sheet 3 may be pasted on the lower surface of upper mold 52. Also if the operation is started from the state illustrated in FIG. 8, the state illustrated in FIG. 3 results when lower mold 51 and upper mold 52 are brought closer to each other. After that, the operation proceeds to the state illustrated in FIG. 4.

In the first state described above, inner frame 11 may be abutting first surface 1a as shown in the present embodiment. By adopting this configuration, substrate 1 can be clamped using inner frame 11.

### Second Embodiment

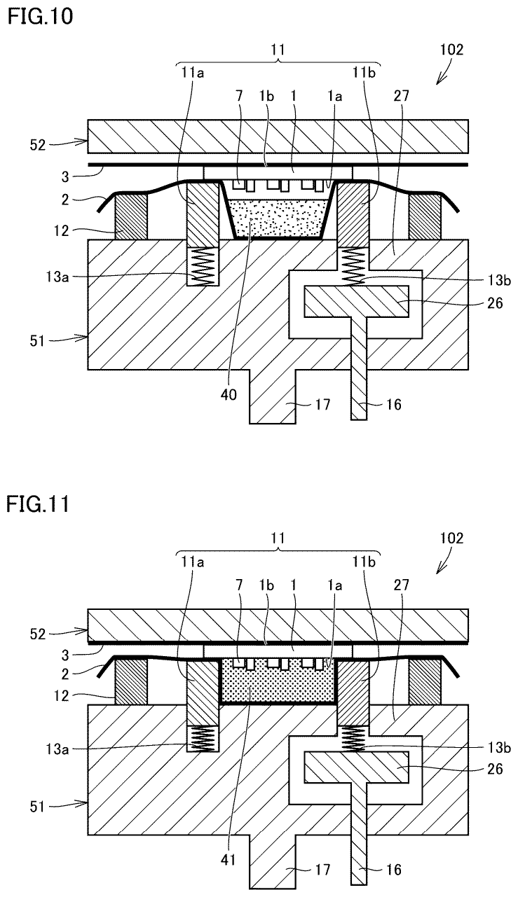

A compression resin sealing molding device according to a second embodiment based on the present disclosure is described with reference to FIGS. 9 to 15. FIG. 9 as a plan view illustrates only an inner frame 11 and an outer frame 12 included in this compression resin sealing molding device. Inner frame 11 includes an inner frame first portion 11a and an inner frame second portion 11b. Inner frame 11 has an annular shape and inner frame second portion 11b is arranged so as to occupy a partial section thereof. The annular shape of inner frame 11 is made by combining inner frame first portion 11a and inner frame second portion 11b. FIG. 10 shows a cross-sectional view according to line X-X with arrows in FIG. 9. However, in FIG. 10, not only inner frame first portion 11a and inner frame second portion 11b but also a wider range of compression resin sealing molding device 102 is illustrated in the cross-sectional view.

Compression resin sealing molding device 102 includes springs 13a and 13b. Inner frame first portion 11a of inner frame 11 is supported by spring 13a. Inner frame second portion 11b of inner frame 11 is supported by spring 13b. Inner frame second portion 11b is displaceable in an up-and-down direction separately from inner frame first portion 11a. The position of inner frame second portion 11b in the up-and-down direction can be determined by moving an inner frame drive shaft 16 in the up-and-down direction.

In the state illustrated in FIG. 10, the outer edge of a substrate 1 is placed over inner frame 11 with a release sheet 2 interposed therebetween. That is, part of the outer edge of substrate 1 is placed over inner frame first portion 11a, and another part thereof is placed over inner frame second portion 11b.

FIG. 11 shows a state in which a lower mold 51 is brought relatively closer to an upper mold 52 from the state illustrated in FIG. 10. In this state, substrate 1 sandwiched between release sheets 2 and 3 is sandwiched and fixed between inner frame 11 of lower mold 51 and upper mold 52. A resin material is melted in a cavity and turns a resin material 41. Resin material 41 is confined inside inner frame 11. Resin material 41 covers part of a first surface 1a of substrate 1. The state illustrated in FIG. 11 is a first state.

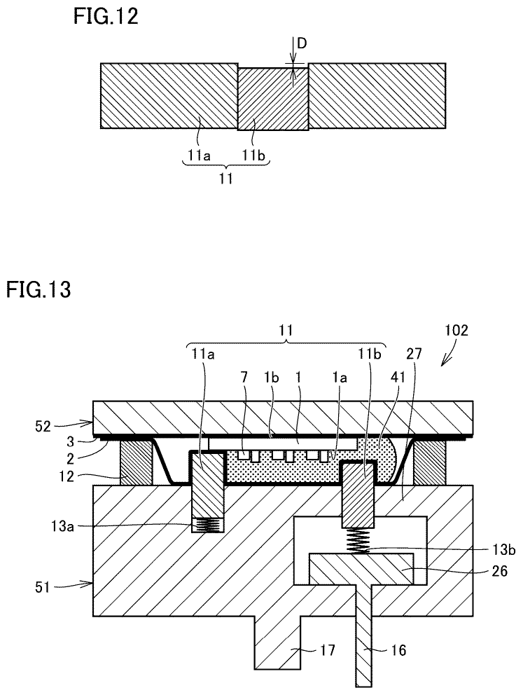

An upper surface of inner frame first portion 11a and an upper surface of inner frame second portion 11b are depicted as having the same height in FIG. 11, but in practice, the upper surface of inner frame second portion 11b may be set so as to be slightly lower. That is, as illustrated in FIG. 12, the upper surface of inner frame second portion 11b may be arranged so as to be lower than the upper surface of inner frame first portion 11a by a depth D. A depressed portion with depth D in this case is formed as a gap that allows air to pass therethrough while resin material 41 does not leak therefrom. This depressed portion is used as a passage for an air vent when resin material 41 is confined by lower mold 51 and upper mold 52. As long as desired internal pressure can be secured, resin material 41 may be leaked from this passage in addition to the air.

The structure of the portions related to inner frame 11 is not limited to the above-described example. For the structure of the portions related to inner frame 11, any mechanism and method may be adopted as long as, when lower mold 51 moves relatively closer to upper mold 52, from the state illustrated in FIG. 10, inner frame first portion 11a and inner frame second portion 11b can reach the state in FIG. 11 by following and becoming lowered and inner frame second portion 11b can reach the state in FIG. 13 by relatively becoming lowered further with respect to member 27.

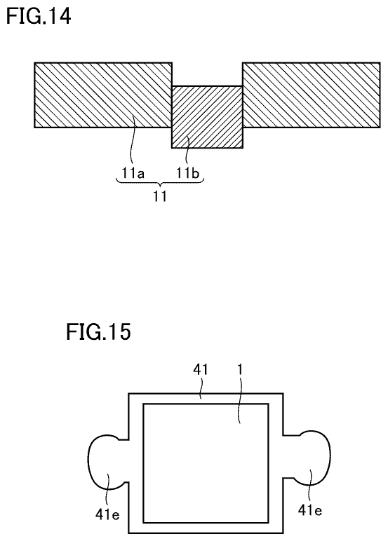

FIG. 13 shows a state in which lower mold 51 is brought relatively still closer to upper mold 52 and inner frame second portion 11b is lowered further from the state illustrated in FIG. 11. In this state, the distance between a portion of lower mold 51 other than outer frame 12 and upper mold 52 is defined by outer frame 12 abutting on a lower surface of upper mold 52. The movement of lowering inner frame second portion 11b can be achieved by lowering inner frame drive shaft 16. Here, inner frame second portion 11b is lowered by a larger dimension, which is not limited to depth D illustrated in FIG. 12. In FIG. 13, a gap is formed between a lower surface of substrate 1 and the upper surface of inner frame second portion 11b, and resin material 41 leaks to the outside accordingly. However, resin material 41 that has leaked outside of inner frame 11 in this manner remains in a region inside outer frame 12. The state illustrated in FIG. 13 is a second state. FIG. 14 shows how inner frame 11 appears in this state. Inner frame second portion 11b is lowered further than inner frame first portion 11a. That is, in the second state, resin material 41 is leaked outside of inner frame 11 by inner frame second portion 11b as part of inner frame 11 becoming displaced away from upper mold 52. In other words, in the second state, the inner frame second portion 11b is vertically displaced away from upper mold 52 more than inner frame first portion 11a, creating a localized path for excess resin material 41 to leak outside of inner frame 11.

Since resin material 41 is hardened in the state where part of resin material 41 is leaked outside of inner frame 11, the molded object obtained appears as in FIG. 15 when shown in a plan view. An upper surface of substrate 1 is exposed, and the leaked resin material 41 is hardened and adheres to the outer periphery thereof in an indefinite shape. Since the leakage of resin material 41 restrictively occurs only in the section where inner frame second portion 11b is arranged, a protruding portion 41e is formed so as to protrude only in the section where inner frame second portion 11b is arranged as illustrated in FIG. 15. Since portion 41e is an unnecessary portion, it is cut off.

Also in the present embodiment, the effects described in the first embodiment can be obtained. In the present embodiment, portion 41e is formed only in a limited location instead of being formed along the entire circumference, and thus, the operation of cutting portion 41e off is facilitated. That is, portion 41e is formed so as to protrude only in a limited portion and is therefore cracked and removed easily. In particular, the split inner frame 11a and 11b limits the excess resin 41e to a small, easily removeable portion.

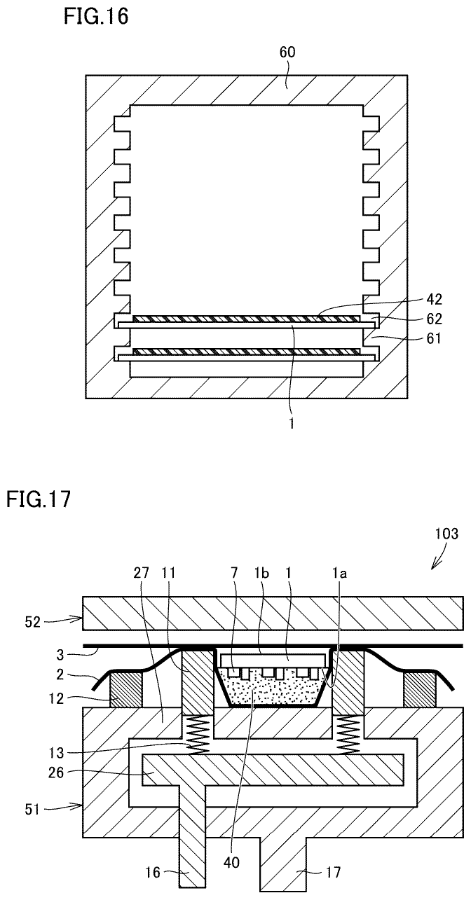

Furthermore, as illustrated in FIG. 16, also when the object after the molding operation is placed on a rack 60, the handling is facilitated. Projections 61 and depressions 62 are formed in left and right inner walls of rack 60 so as to extend in a front-back direction. The object is placed by being slid to the back along depressions 62 so that left and right end portions of the object are placed on projections 61. At the time of taking the object out from rack 60, the object is slid forward along depressions 62 to be taken out.

In the present embodiment, portion 41e is not formed on a side of the four sides where inner frame second portion 11b is not arranged. Accordingly, by adopting a configuration in which inner frame second portion 11b is not arranged on the two sides of substrate 1 parallel to each other, it is enabled to achieve a linear state in which protruding portion 41e is not formed at all on the two sides parallel to each other in a state after the molding. Thus, the placement and takeout with respect to rack 60 can be smoothly performed without anywhere being caught.

As shown in the present embodiment, by providing a slight difference in height between the respective upper surfaces of inner frame first portion 11a and inner frame second portion 11b to secure a passage for an air vent, air escape at the time of pressing the resin material is improved, and the filling with resin material 41 around component 7 can be performed reliably. The improvement in the air escape hinders generation of a void.

### Third Embodiment

A compression resin sealing molding device according to a third embodiment based on the present disclosure is described with reference to FIGS. 17 to 19. FIG. 17 shows an initial state of compression resin sealing molding device 103 according to the present embodiment.

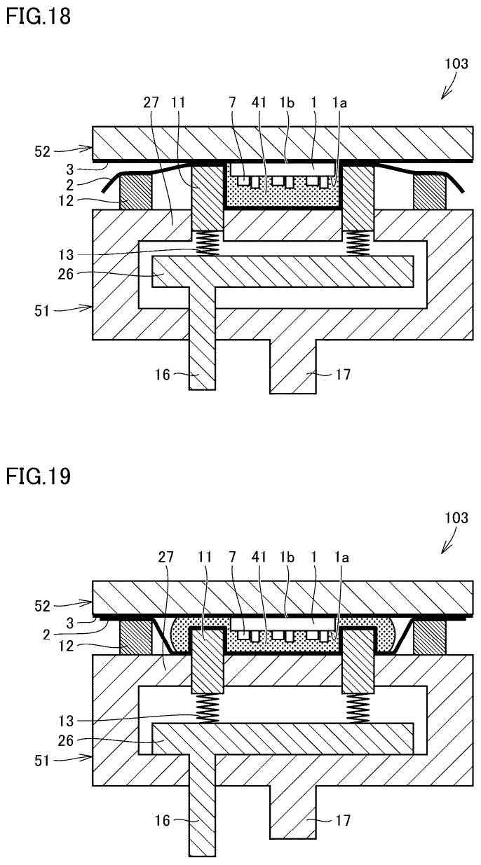

In compression resin sealing molding device 103, an inner frame 11 is not abutting on a first surface 1a of a substrate 1. Substrate 1 is placed over a powder resin material 40. Substrate 1 is housed inside inner frame 11. Substrate 1 and powder resin material 40 are housed in a depressed portion of a release sheet 2. FIG. 18 shows a state in which a lower mold 51 is brought relatively closer to an upper mold 52 from this state. The resin material is melted in a cavity and turns a resin material 41. Resin material 41 is confined inside inner frame 11. Resin material 41 covers the entire first surface 1a of substrate 1. The state illustrated in FIG. 18 is a first state.

In the first state described above, inner frame 11 is abutting on upper mold 52 in a position where inner frame 11 surrounds substrate 1.

FIG. 19 shows a state in which lower mold 51 is brought relatively still closer to upper mold 52 and inner frame 11 is slightly lowered further from the state illustrated in FIG. 18. The movement of lowering inner frame 11 can be achieved by lowering an inner frame drive shaft 16. In FIG. 19, a gap is formed between a lower surface of substrate 1 and an upper surface of inner frame 11, and resin material 41 leaks to the outside accordingly. However, resin material 41 that has leaked outside of inner frame 11 in this manner remains in a region inside outer frame 12. The state illustrated in FIG. 19 is a second state.

Also in the present embodiment, the effects described in the first embodiment can be obtained.

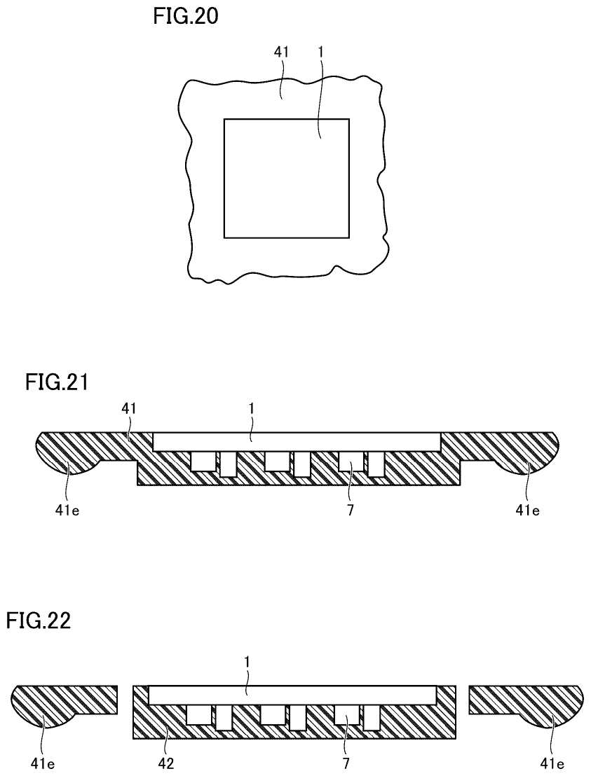

Since in the present embodiment, substrate 1 is not restrained in a thickness direction, the degree of damage inflicted on substrate 1 can be reduced. When the difference between the inner size of inner frame 11 and the size of substrate 1 is made small, the resin material can be molded in a state where substrate 1 is restrained in a horizontal direction but is not restrained in the thickness direction. In compression resin sealing molding device 103 according to the present embodiment, as illustrated in FIG. 20, the molding is performed in a state where the resin material spreads to be larger than the size of substrate 1. In this case, the state illustrated in FIG. 21 results. A protruding portion 41e may be cut off as illustrated in FIG. 22.

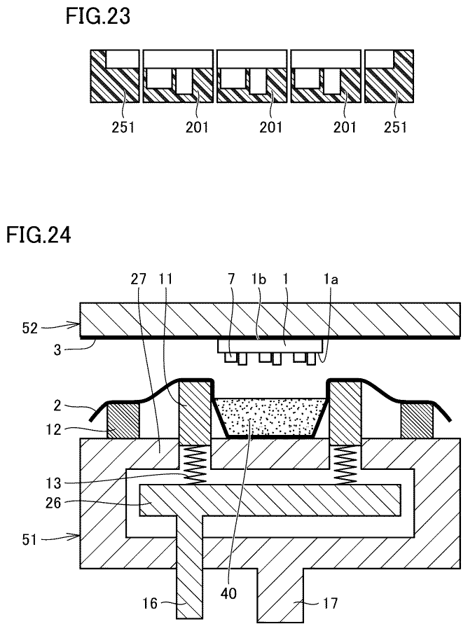

Furthermore, as illustrated in FIG. 23, cutting separation is performed according to the size of each individual module 201 as necessary. At this time, an outer peripheral portion is cut out as an unnecessary portion 251.

In the present embodiment, when the positional accuracy between substrate 1 and a sealing resin layer 42 is favorable, a resin molded portion of the outer peripheral portion that is to be a waste can be controlled so as to be small. When resin material 41 is leaked by lowering inner frame 11 as illustrated in FIG. 19, it is necessary to make the thickness of the passage through which resin material 41 leaks smaller than the thickness of substrate 1 so as to prevent substrate 1 from moving in the horizontal direction and overlapping inner frame 11.

In the present embodiment, the operation is started from the state in which substrate 1 is placed over powder resin material 40 on the lower mold 51 side but the operation may be started from the state in which substrate 1 is held toward upper mold 52 as illustrated in FIG. 24. In FIG. 24, a release sheet 3 is held on a lower surface of upper mold 52 and substrate 1 is held on a lower surface of release sheet 3. Also if the operation is started from the state illustrated in FIG. 24, the state illustrated in FIG. 18 results when lower mold 51 and upper mold 52 are brought closer to each other. After that, the operation proceeds to the state illustrated in FIG. 19.

### Fourth Embodiment

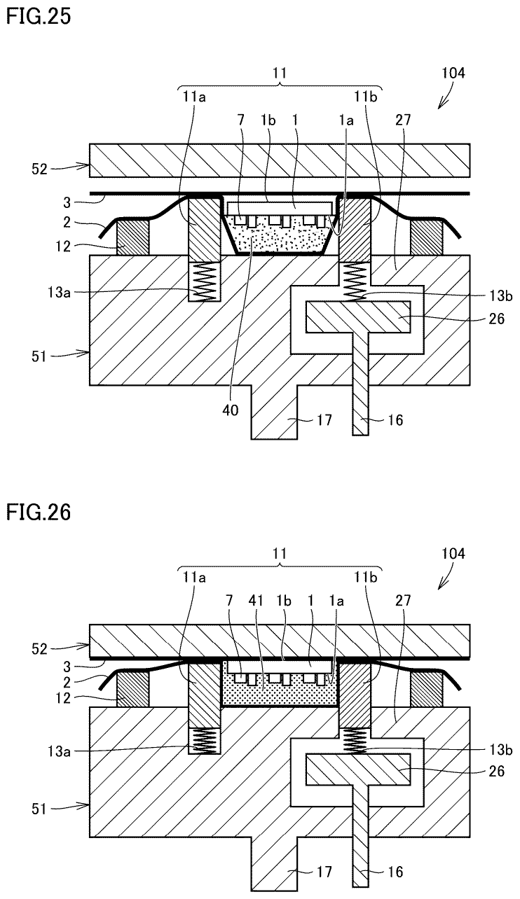

A compression resin sealing molding device according to a fourth embodiment based on the present disclosure is described with reference to FIGS. 25 to 28. FIG. 25 shows an initial state of compression resin sealing molding device 104 according to the present embodiment.

In compression resin sealing molding device 104, similarly to the third embodiment, a substrate 1 is housed inside an inner frame 11. Furthermore, similarly to the second embodiment, inner frame 11 includes an inner frame first portion 11a and an inner frame second portion 11b. Inner frame second portion 11b is displaceable in an up-and-down direction separately from inner frame first portion 11a.

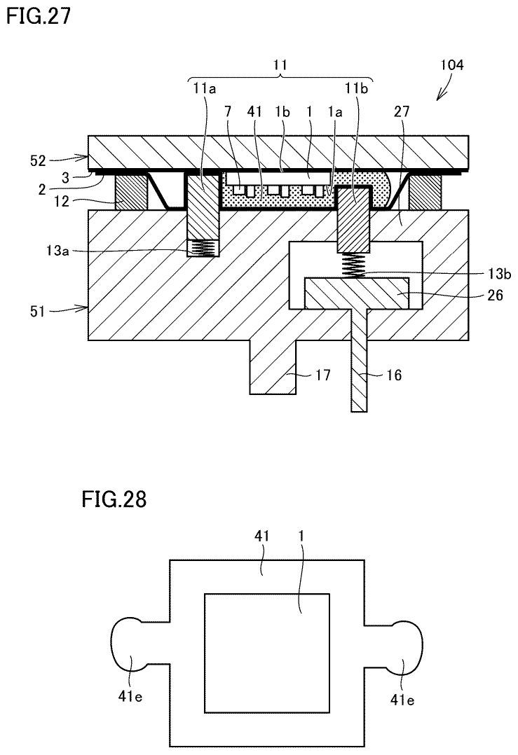

FIG. 26 shows a state in which a lower mold 51 is brought relatively closer to an upper mold 52 from the state illustrated in FIG. 25. A resin material is melted in a cavity and turns a resin material 41. Resin material 41 is confined inside inner frame 11. FIG. 27 shows a state in which lower mold 51 is brought relatively still closer to upper mold 52 and inner frame second portion 11b is slightly lowered further from the state illustrated in FIG. 26. In FIG. 27, a gap is formed between a lower surface of substrate 1 and an upper surface of inner frame second portion 11b, and resin material 41 leaks to the outside accordingly.

Since resin material 41 is hardened in the state where part of resin material 41 is leaked outside of inner frame 11, the resultant object obtained appears as in FIG. 28 when shown in a plan view. Since the leakage of resin material 41 restrictively occurs only in the section where inner frame second portion 11b is arranged, a protruding portion 41e is formed so as to protrude only in the section where inner frame second portion 11b is arranged as illustrated in FIG. 28.

Also in the present embodiment, the effects described in the first embodiment can be obtained. Moreover, in the present embodiment, the effects in both of the second embodiment and the third embodiment can be obtained.

### Fifth Embodiment

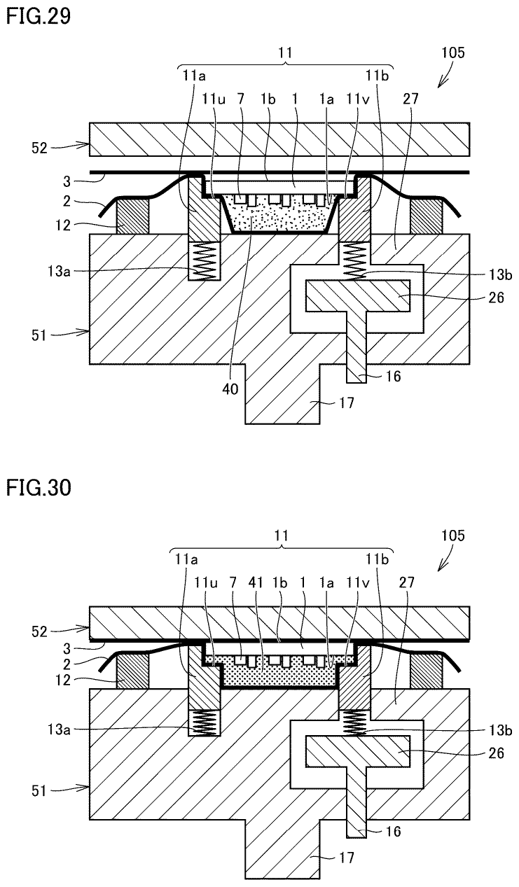

A compression resin sealing molding device according to a fifth embodiment based on the present disclosure is described with reference to FIGS. 29 to 31. FIG. 29 shows an initial state of compression resin sealing molding device 105 according to the present embodiment.

In compression resin sealing molding device 105, a step is provided in an inner frame 11. That is, an inner frame first portion 11a is provided with a step portion 11u, and an inner frame second portion 11b is provided with a step portion 11v. A substrate 1 is placed so as to be caught by step portions 11u and 11v. The other configurations are the same as those described in the second embodiment.

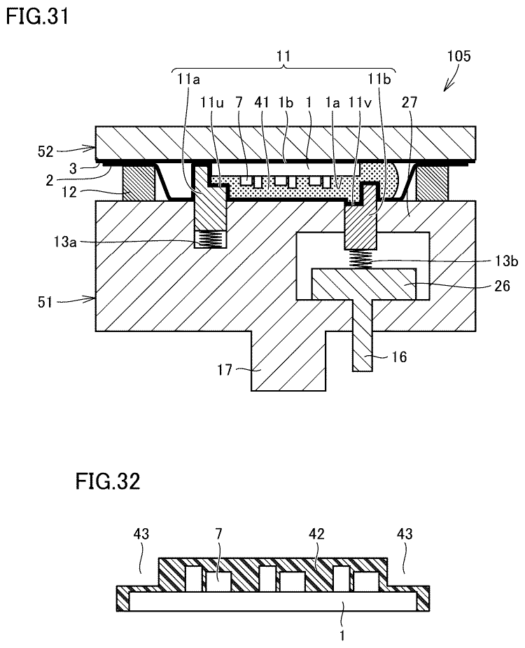

FIG. 30 shows a state in which a lower mold 51 is brought relatively closer to an upper mold 52 from the state illustrated in FIG. 29. A resin material is melted in a cavity and turns a resin material 41. Resin material 41 is confined inside inner frame 11. FIG. 31 shows a state in which lower mold 51 is brought relatively still closer to upper mold 52 and inner frame second portion 11b is slightly lowered further from the state illustrated in FIG. 30. In FIG. 31, a gap is formed between a lower surface of substrate 1 and an upper surface of inner frame second portion 11b, and resin material 41 leaks to the outside accordingly.

In the present embodiment, inner frame 11 includes a first height portion abuttable on upper mold 52, and a second height portion situated inside the first height portion and capable of overlapping substrate 1. The steps caused by the difference between the first height portion and the second height portion are step portions 11u and 11v.

Also in the present embodiment, the effects described in the first embodiment can be obtained.

FIG. 32 shows a molded object obtained in compression resin sealing molding device 105 according to the present embodiment. FIG. 32 is a cross-sectional view taken along a cross section that extends across only a portion that abuts on inner frame first portion 11a rather than a portion that abuts on inner frame second portion 11b. As illustrated in FIG. 32, a sealing resin layer 42 is formed. However, a cutout portion 43 is formed in the vicinity of the outer periphery of the molded object. In cutout portion 43, the thickness of sealing resin layer 42 is made small.

In the vicinity of the outer periphery of substrate 1, there is a region in which no component is mounted despite the fact that the region is on substrate 1, but in the present embodiment, cutout portion 43 can be formed in sealing resin layer 42 in such a region. Accordingly, the amount of the resin used can be reduced.

As shown in the present embodiment, the first height portion and the second height portion may be integrally formed. By adopting this configuration, the number of components can be decreased.

### Sixth Embodiment

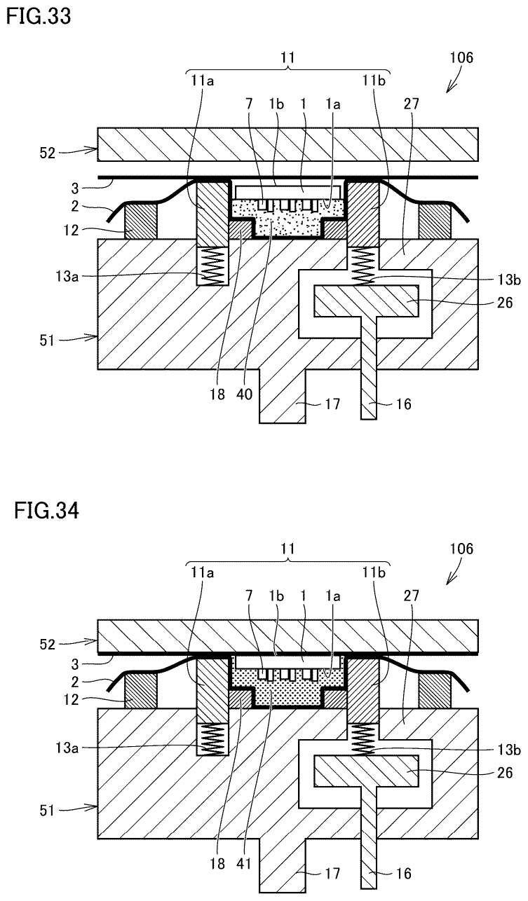

A compression resin sealing molding device according to a sixth embodiment based on the present disclosure is described with reference to FIGS. 33 to 35. FIG. 33 shows an initial state of compression resin sealing molding device 106 according to the present embodiment.

In compression resin sealing molding device 106, a bottom raising portion 18 is arranged further inside an inner frame 11. Bottom raising portion 18 is fixed to an upper surface of a member 27. Bottom raising portion 18 is not limited to a separate member but may be formed by causing part of member 27 to project. An inner frame first portion 11a and an inner frame second portion 11b are each not provided with a step portion. The other configurations are the same as those described in the third embodiment.

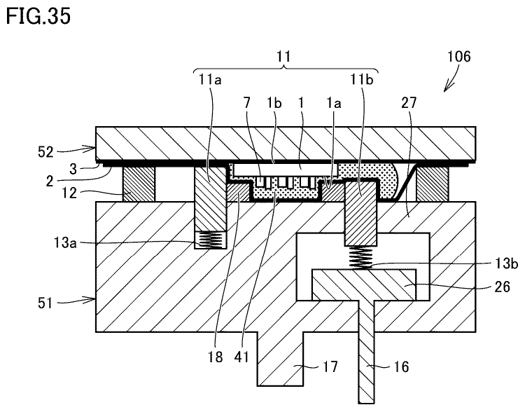

FIG. 34 shows a state in which a lower mold 51 is brought relatively closer to an upper mold 52 from the state illustrated in FIG. 33. A resin material is melted in a cavity and turns a resin material 41. Resin material 41 is confined inside inner frame 11. FIG. 35 shows a state in which lower mold 51 is brought relatively still closer to upper mold 52 and inner frame second portion 11b is slightly lowered further from the state illustrated in FIG. 34. In FIG. 35, a gap is formed between a lower surface of a substrate 1 and an upper surface of inner frame second portion 11b, and resin material 41 leaks to the outside accordingly.

Inner frame 11 includes a first height portion abuttable on upper mold 52. Lower mold 51 is provided with a second height portion situated inside inner frame 11 and capable of overlapping substrate 1 without being in contact with substrate 1. In the present embodiment, bottom raising portion 18 is the second height portion.

Also in the present embodiment, the same effects as those described in the fifth embodiment can be obtained.

Two or more of the above-described embodiments may be appropriately combined and adopted.

According to embodiments, the device achieves a desired product thickness by precisely controlling the relative travel between the lower mold 51 and the upper mold 52. The outer frame 12 is configured to abut the upper mold 52 outside the substrate, thereby establishing a fixed minimum gap, which defines the predetermined final package thickness, and establishing a maximum compression distance which directly corresponds to the final package thickness of the sealed product. The inner frame 11 manages the resin in two states: first, achieving pressurization through elastic deformation for void-free filling ; and second, achieving controlled leakage by displacement to discharge excess resin material into the overflow region once the maximum compression distance is reached. The pressurization in the first state is facilitated by supporting the inner frame with an elastic body 13, 13a, 13b that undergoes elastic deformation when engaged by the upper mold 52. In embodiments utilizing a split inner frame, such as the second, fourth, and sixth embodiments, the vertically independent displacement of the inner frame second portion creates a localized resin leakage path, which confines the leaked material to a specific area to facilitate easier post-molding removal.

The herein-disclosed foregoing embodiments are presented by way of illustration and example in all respects and are not to be taken by way of limitation.

The scope of the present invention is defined by the claims and encompasses all changes within the meaning and scope equivalent to the claims.

### Appendices

### Appendix 1

A compression resin sealing molding device for molding a sealing resin layer so as to cover at least part of a first surface of a substrate while sealing a component arranged on the first surface of the substrate, the substrate including the first surface and a second surface opposite to each other, the compression resin sealing molding device comprising:
a lower mold facing the first surface; and
an upper mold that abuts on the second surface, wherein
the lower mold includes an outer frame and an inner frame, at least part of the inner frame being relatively displaceable in an up-and-down direction with respect to the outer frame,
the outer frame is abuttable on the upper mold outside the substrate,
the inner frame is capable of taking a first state in which a resin material being a material of the sealing resin layer is confined in an inner region of the inner frame and pressurized, and a second state in which part of the resin material is held in the inner region of the inner frame while another part of the resin material is leaked to an outside of the inner frame, and
a distance between a portion of the lower mold other than the outer frame and the upper mold at a time when the lower mold and the upper mold are closest to each other is determined by the outer frame abutting on the upper mold.

### Appendix 2

The compression resin sealing molding device according to Appendix 1, wherein in the first state, the inner frame is abutting on the first surface.

### Appendix 3

The compression resin sealing molding device according to Appendix 1, wherein in the first state, the inner frame is abutting on the upper mold in a position where the inner frame surrounds the substrate.

### Appendix 4

The compression resin sealing molding device according to Appendix 3, wherein the inner frame includes a first height portion abuttable on the upper mold, and a second height portion situated inside the first height portion and capable of overlapping the substrate.

### Appendix 5

The compression resin sealing molding device according to Appendix 4, wherein the first height portion and the second height portion are integrally formed.

### Appendix 6

The compression resin sealing molding device according to Appendix 3, wherein
the inner frame includes a first height portion abuttable on the upper mold, and
the lower mold includes a second height portion inside the inner frame, the second height portion being capable of overlapping the substrate without being in contact with the substrate.

### Appendix 7

The compression resin sealing molding device according to any one of Appendices 1 to 6, wherein in the second state, the resin material is leaked outside of the inner frame by part of the inner frame becoming displaced away from the upper mold.

### Appendix 8

The compression resin sealing molding device according to any one of Appendices 1 to 7, wherein the inner frame is supported with an elastic body interposed in between, and in the first state, the resin material confined in the inner region of the inner frame is pressurized through elastic deformation of the elastic body on the inner frame.

### REFERENCE SIGNS LIST

1 substrate; 1a first surface; 1b second surface; 2, 3 release sheet; 7 component; 11 inner frame; 11a inner frame first portion; 11b inner frame second portion; 11u, 11v step portion; 12 outer frame; 13, 13a, 13b spring; 15 base; 16 inner frame drive shaft; 17 base drive shaft; 18 bottom raising portion; 26, 27 member; 40 powder resin material; 41 resin material; 41e (protruding and projecting) portion; 42 sealing resin layer; 43 cutout portion; 51 lower mold; 52 upper mold; 60 rack; 61 projection; 62 depression; 101, 102, 103, 104, 105, 106 compression resin sealing molding device; 201 module; 251 unnecessary portion.

1. A compression resin sealing molding device for molding a sealing resin layer on a substrate having a first surface and a second surface opposite to each other, the device comprising:
a lower mold facing the first surface; and
an upper mold configured to abut the second surface, wherein
the lower mold including an outer frame and an inner frame, at least part of the inner frame being vertically displaceable and the outer frame being vertically displaceable with respect to one another,
the outer frame is configured to abut the upper mold outside the substrate to determine a fixed minimum gap between the lower mold and the upper mold that defines a final product thickness,
the inner frame is configured to transition between:
a first state in which a resin material provided for sealing the substrate is confined and pressurized in an inner region of the inner frame, and
a second state in which part of the resin material is held in the inner region of the inner frame while excess resin material is leaked to an overflow region outside the inner frame, the second state being achieved when the outer frame abuts the upper mold.

2. The compression resin sealing molding device according to claim 1, wherein in the first state, the inner frame abuts the first surface.

3. The compression resin sealing molding device according to claim 1, wherein in the first state, the inner frame abuts the upper mold in a position where the inner frame surrounds the substrate.

4. The compression resin sealing molding device according to claim 3, wherein the inner frame includes a first height portion abuttable on the upper mold, and a second height portion situated inside the first height portion and capable of overlapping the substrate.

5. The compression resin sealing molding device according to claim 4, wherein the first height portion and the second height portion are integrally formed.

6. The compression resin sealing molding device according to claim 3, wherein
the inner frame includes a first height portion abuttable on the upper mold, and
the lower mold includes a second height portion inside the inner frame, the second height portion being capable of overlapping the substrate without being in contact with the substrate.

7. The compression resin sealing molding device according to claim 1, wherein transition to the second state, includes part of the inner frame becoming vertically displaced away from the upper mold.

8. The compression resin sealing molding device according to claim 1, wherein the inner frame is supported with an elastic body interposed in between, and in the first state, the resin material confined in the inner region of the inner frame is pressurized through elastic deformation of the elastic body on the inner frame.

9. The compression resin sealing molding device according to claim 1, wherein the lower mold further includes a first member supporting the inner frame and a second member supporting the outer frame.

10. The compression resin sealing molding device according to claim 1, wherein
the inner frame includes an inner frame first portion and an inner frame second portion, and
the inner frame second portion is vertically displaceable independent of the inner frame first portion.

11. The compression resin sealing molding device according to claim 10, wherein the inner frame second portion has a height difference lower than the inner frame first portion in the first state, creating a passage for an air vent.

12. The compression resin sealing molding device according to claim 1, wherein the lower mold includes a bottom raising portion inside the inner frame that can overlap the substrate without being in contact with the substrate.

13. The compression resin sealing molding device according to claim 1, further comprising an inner frame drive shaft configured to vertically displace the inner frame.

14. A compression resin sealing molding device for molding a sealing resin layer on a substrate to a predetermined final thickness, the substrate having a first surface and a second surface opposite each other, the device comprising:
a lower mold facing the first surface; and
an upper mold configured to abut the second surface, wherein the lower mold includes
an outer frame and an inner frame, the inner frame including an inner frame first portion and an inner frame second portion;
the outer frame being configured to abut the upper mold outside the substrate to establish a fixed final thickness;
the inner frame being configured to pressurize a resin material in a first state; and
the inner frame second portion being vertically displaceable independent of the inner frame first portion to create a localized leakage path for excess resin material in a second state, the second state being achieved when the outer frame abuts the upper mold.

15. A method of compression resin sealing a substrate to a predetermined thickness, comprising:
(a) placing a resin material and the substrate into a lower mold having an outer frame and an inner frame that are vertically displaceable relative to one another;
(b) bringing an upper mold and the lower mold together to confine and pressurize the resin material in a first state;
(c) continuing the movement of the lower mold and the upper mold relative to one another until the outer frame abuts the upper mold, thereby establishing the predetermined thickness, and simultaneously displacing the inner frame to intentionally leak excess resin material into an overflow region to achieve a second state; and
(d) hardening the resin material in the second state.
